(19) United States
(12) Patent Application Publication
(10) Pub. No.: US 2023/0232607 A1
(43) Pub. Date: Jul. 20, 2023

(54) SEMICONDUCTOR DEVICE STRUCTURE AND METHOD MAKING THE SAME

(71) Applicant: ChangXin Memory Technologies, Inc., Hefei City (CN)

(72) Inventor: Jinil LEE, Hefei City (CN)

(21) Appl. No.: 17/420,124

(22) PCT Filed: Dec. 3, 2020
(86) PCT No.: PCT/CN2020/133567

§ 371 Date: Mar. 27, 2023

(30) Foreign Application Priority Data
Feb. 27, 2020 (CN) 202010123360.6

(51) Int. Cl. H10B 12/00

(52) U.S. Cl. CPC H10B 12/0387; H10B 12/373; H01L 28/91

(57) ABSTRACT

The present disclosure is in the field of semiconductor devices, in particular, to a semiconductor structure and a method of forming the same. The semiconductor structure includes: a substrate with a trench extending in a direction of the substrate; a capacitor fabricated in the trench, the capacitor includes a lower electrode disposed on an inner wall of the trench, a dielectric combination layer disposed on the lower electrode, and an upper electrode disposed on the dielectric combination layer; the dielectric combination layer includes a stacked structure composed of a nitride layer and an oxide layer. The device can increase the capacitance of the capacitor significantly and reduce the occurrence of charge leakage, thereby improving the electrical performance of the semiconductor memory device.

### CROSS REFERENCES TO RELATED APPLICATIONS

This application claims the benefit of priority to CN Patent Application 202010123360.6 filed on Feb. 27, 2020, both entitled “SEMICONDUCTOR DEVICE STRUCTURE AND METHOD MAKING THE SAME”, the contents of which are incorporated herein by reference in its entirety.

### TECHNICAL FIELD

The present disclosure relates to the technical field of semiconductor manufacturing, in particular to a semiconductor structure and a method of forming the same.

### BACKGROUND

As the critical dimensions of semiconductor devices continue to shrink in accordance with Moore's Law, the capacitances of DRAM capacitors have been continuously reduced. Most of capacitors in existing DRAMs are cylindrical capacitors with a high aspect ratio. However, as the sizes of the DRAMs continue to shrink, the spaces used to form the electrodes and the dielectrics in the cylindrical capacitors are getting smaller and smaller, which eventually leads to significant decreases in the capacitance values of cylindrical capacitors. The reduction of the capacitance values will seriously affect DRAM performance.

Therefore, how to maintain a high capacitance value while keeping DRAM size reduced so to improve DRAM's performance has become an urgent problem to solve.

### SUMMARY

The present disclosure provides a semiconductor structure and a forming method thereof, in order to solve the existing low capacitance problem and improve the performance of the semiconductor memory devices.

According to some embodiments of the disclosure, a semiconductor structure is provided, comprising: a substrate comprising a trench extending along a direction of the substrate; a capacitor fabricated in the trench, wherein the capacitor comprises a lower electrode provided on an inner wall of the trench, a dielectric combination layer provided on the lower electrode, and an upper electrode provided on the dielectric combination layer; wherein the dielectric combination layer comprises a stacked structure composed of a nitride layer and an oxide layer.

In some cases, the substrate further comprises a first-type doped region and a second-type doped region located above the first-type doped region, wherein the trench passes through the second-type doping region and extends to the first-type doped region, and wherein the lower electrode is disposed on the inner wall of the trench in the first-type doped region.

In some cases, the dielectric combination layer is disposed in the trench in the first-type doped region.

In some cases, the structure further comprising a capacitor contact structure formed above the upper electrode and electrically connected to the upper electrode.

In some cases, the structure further comprising an isolation structure formed above the lower electrode, wherein the isolation structure is disposed on a top surface of a side wall of the lower electrode, for isolating the lower electrode from the capacitor contact structure.

In some cases, the oxide layer comprises one or more of ZrO2, Ta2O5, Al2O3, TiO2, and HfO2.

According to another embodiment, a method for forming a semiconductor structure, comprises a plurality of steps: providing a substrate comprising a trench extending along a direction of the substrate; fabricating a capacitor in the trench, wherein the capacitor comprises a lower electrode disposed on an inner wall of the trench, a dielectric combination layer disposed on the lower electrode, and an upper electrode disposed on the dielectric combination layer, wherein the dielectric combination layer comprises a stacked structure composed of a nitride layer and an oxide layer.

In some cases, the substrate further comprises a first-type doped region and a second-type doped region located above the first-type doped region, wherein the trench passes through the second-type doped region and extends to the first-type doped region; and wherein the fabricating the capacitor in the trench comprises: forming the lower electrode on the inner wall of the trench in the first-type doped region.

In some cases, the dielectric combination layer is disposed in the trench in the first-type doped region, and wherein the dielectric combination layer is disposed on a surface of the lower electrode.

In some cases, after fabricating the capacitor in the trench, the method further comprises forming a capacitor contact structure electrically connected to the upper electrode.

In some cases, the method further comprises forming an isolation structure above the lower electrode, wherein the isolation structure is disposed on an upper surface of the lower electrode for isolating the lower electrode from the capacitor contact structure.

In some cases, the oxide layer comprises one or more of ZrO2, Ta2O5, Al2O3, TiO2, and HfO2.

The semiconductor structure does not have to reduce the area of the lower electrode, the dielectric layer, and the upper electrode as the DRAM size shrinks, thus helps with keeping the capacitance at a higher level, thereby improving the electrical performance of the DRAM. In addition, the capacitor forming has applied trench filling process, which simplifies the capacitor formation process, optimizes the overall shape of the capacitor, and ensures the performance stability of the DRAM. Also, by adopting a dielectric combination layer including a stacked structure composed of nitride and oxide, not only the leakage phenomenon is avoided, but also the overall dielectric constant of the dielectric combination layer is effectively increased, thereby further increases the capacitor's capacitance and improves the electrical performance of the semiconductor structure.

It should be understood that the above general description and the following detailed description are only exemplary and cannot limit the present disclosure.

### BRIEF DESCRIPTION OF THE DRAWINGS

By describing its exemplary embodiments in detail with reference to the accompanying drawings, the above and other objectives, features and advantages of the present disclosure will become more apparent.

FIG. 1 shows a schematic cross-sectional view of a semiconductor structure from an angle according to one embodiment of the present disclosure;

FIG. 2 shows a schematic cross-sectional view of a semiconductor structure from another angle according to one embodiment of the present disclosure;

FIG. 3 shows a schematic diagram of a partial circuit structure of a semiconductor structure according to one embodiment of the present disclosure;

FIG. 4 shows a flowchart of the method for forming the semiconductor structure according to one embodiment of the present disclosure; and

FIGS. 5A-5E are schematic cross-sectional views of the semiconductor structure at main steps in the forming process according to one embodiment of the present disclosure.

### DETAILED DESCRIPTION OF THE PREFERRED EMBODIMENTS

Implementations of the present disclosure are illustrated below through specific embodiments. Those skilled in the art can easily understand other advantages and efficacy of the present disclosure according to the content disclosed in this specification. The present disclosure can also be implemented or applied through other different specific implementations. Various modifications or variations can also be made on details in this specification based on different opinions and applications without departing from the spirit of the present disclosure.

It should be noted that, the figures provided in this embodiment merely illustrate the basic conception of the present disclosure schematically. Therefore, the figures only show components related to the present disclosure, and are not drawn according to the quantity, shapes and sizes of components during actual implementation. The pattern, quantity and ratio of components during actual implementation can be changed arbitrarily, and the component layout may also be more complex.

The present disclosure effectively overcomes various disadvantages in the prior arts and hence has high industrial usage value. The foregoing embodiments only illustrate the principle and efficacy of the present disclosure exemplarily, and are not meant to limit variations of the technique. Any person skilled in the art can make modifications on the foregoing embodiments without departing from the spirit and scope of the present disclosure. Accordingly, all equivalent modifications or variations completed by those with ordinary skill in the art without departing from the spirit and technical thinking disclosed by the present disclosure should fall within the scope of claims of the present disclosure.

Example embodiments will now be described more fully with reference to the accompanying drawings. However, the example embodiments can be implemented in various forms, and should not be construed as being limited to the examples set forth herein; on the contrary, the provision of these embodiments makes the present disclosure more comprehensive and complete, and fully conveys the concept of the example embodiments to those skilled in the art. The drawings are only schematic illustrations of the present disclosure and are not necessarily drawn to scale. The same reference numerals in the figures denote the same or similar parts, and thus their repeated description will be omitted.

Furthermore, the described features, structures or characteristics can be combined in one or more embodiments in any suitable manner. In the following description, many specific details are provided to give a sufficient understanding of the embodiments of the present disclosure. However, those skilled in the art will realize that the technical solutions of the present disclosure can be practiced without one or more of the specific details, or other methods, components, devices, steps, etc. can be used. In other cases, well-known structures, methods, devices, implementations, or operations are not shown or described in detail to avoid overwhelming attention and obscure all aspects of the present disclosure.

In addition, the terms “first” and “second” are only used for descriptive purposes, and cannot be understood as indicating or implying relative importance or implicitly indicating the number of indicated technical features. Thus, the features defined with “first” and “second” may explicitly or implicitly include one or more of these features.

The specific embodiments of the semiconductor structure and its forming method provided by the present disclosure will be described in detail below in conjunction with the accompanying drawings.

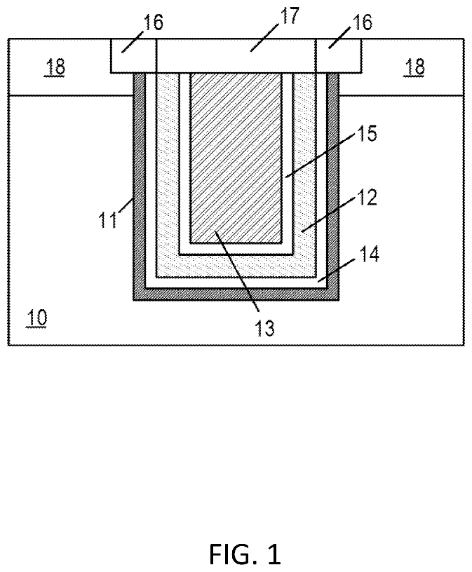

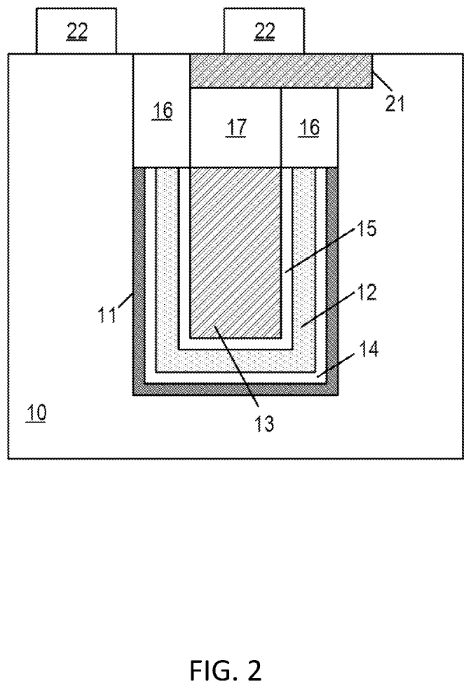

This embodiment provides a semiconductor structure as shown from one angle in the cross-sectional view in FIG. 1. FIG. 2 shows a cross-sectional view of the semiconductor structure from another angle. As shown in FIG. 1 and FIG. 2, the semiconductor structure provided by this embodiment includes: a substrate has a trench extending in a direction of the substrate; a capacitor is disposed in the trench. The capacitor includes a lower electrode 11 disposed on the inner wall of the trench, a dielectric combination layer disposed on the lower electrode 11, and an upper electrode 13 disposed on the dielectric combination layer;

The dielectric combination layer includes a stacked structure composed of nitride and oxide.

Specifically, the material of the substrate may be silicon but not limited to it. The substrate includes a region 10 doped with the first-type of dopant, and a region 18 doped with second-type of dopant, the region 18 is located above the first-type doped region 10. The conductivity types of the second-type doped region 18 and the first-type doped region 10 are opposite. For example, the first-type doped region 10 is doped with P-type ions, and the second-type doped region 18 is doped with N-type ions, or the first-type doped region 10 is doped with N-type ions, and the second-type doped region 18 is doped with P-type ions. The trench extends in a direction perpendicular to the substrate. The lower electrode 11 covers the sidewall and bottom wall of the trench, and the dielectric combination layer is disposed in the trench and covers the surface of the electrode 11 opposite from the surface of the inner wall of the trench, the upper electrode 13 is disposed in the trench and covers the surface of the dielectric combination layer opposite from the lower electrode 11. The upper electrode 13 fills the area surrounded by the dielectric combination layer like a plug.

The dielectric combination layer includes a stacked structure composed of nitride and oxide, where nitride and oxide are stacked in a radial direction of the trench. The nitride may be located on the surface of the oxide facing the lower electrode 11, may also be located on the surface of the oxide facing the upper electrode 13, and may also be located on the surface of the oxide facing the lower electrode 11 surface, or on the surface of the oxide facing the upper electrode 13 (that is, the nitride is located on both opposite sides of the oxide), all these configurations can be set by those skilled in the art according to actual needs.

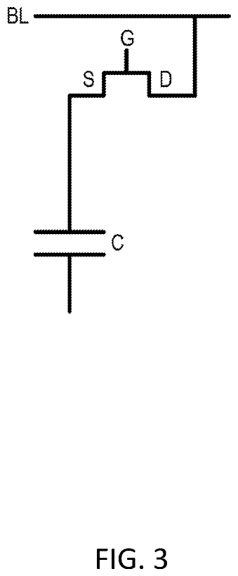

FIG. 3 is a schematic diagram of a partial circuit of the semiconductor device according to an embodiment of the present disclosure. As shown in FIG. 2 and FIG. 3, in this embodiment, the capacitor C and the transistor are both disposed in the substrate, and the capacitor is disposed under the transistor, and the gate G of the transistor is electrically connected to the word line 22, the source S is electrically connected to the capacitor, and the drain D is electrically connected to the bit line BL. The capacitor and the word line 22 are electrically isolated by an STI (shallow trench isolation structure) 21.

The material of the lower electrode 11 and the upper electrode 13 may be, but not limited to, a metal material (such as metal tungsten) or a polysilicon material. For example, the material of the lower electrode 11 and the upper electrode 13 is N-type ions doped polysilicon or P-type ions doped polysilicon. When the lower electrode 11 is a polysilicon material doped with N-type ions, and the first-type doped region 10 is a silicon substrate also doped with N-type ions. The dopants in the lower electrode 11 and the first-type doped region 10 may be the same or can be different; the dopant concentration in the lower electrode 11 may be 10¹⁹ cm⁻³, and the dopant concentration in the first-type doped region 10 can be 10¹⁷ cm⁻³.

In this embodiment, a trench is formed in the substrate 10 and a trench capacitor is fabricated in the trench. This structure does not have to reduce the area of the lower electrode, the dielectric layer, and the upper electrode as the DRAM size shrinks, thus helps with keeping the capacitance at a higher level, thereby improving the electrical performance of the DRAM. In addition, the capacitor forming has applied trench filling process, which simplifies the capacitor formation process, optimizes the overall shape of the capacitor, and ensures the performance stability of the DRAM. Also, by adopting a dielectric combination layer including a stacked structure composed of nitride and oxide, not only the leakage phenomenon is avoided, but also the overall dielectric constant of the dielectric combination layer is effectively increased, thereby further increases the capacitor's capacitance and improves the electrical performance of the semiconductor structure.

The specific dimensions of the trench (for example, the depth and width of the trench) can be set by users according to actual needs, for example, according to the capacitance value required by the DRAM device. Optionally, the depth of the trench is 15 μm-100 μm.

Optionally, the substrate includes a first-type doped region 10 and a second-type doped region 18 located above the first-type doped region 10, and the trench passes through the second-type doped region 18 and extends to the first-type doped region 10, and the lower electrode 11 covers the inner walls of the trench in the first-type doped region 10.

Optionally, the dielectric combination layer is located in the trench in the first-type doped region 10.

Specifically, the trench penetrates the second-type doped region 18 and extends to the inside of the first-type doped region 10, and both the lower electrode 11 and the dielectric combination layer cover at least the inner walls of the trench in the first doped region 11. For example, both the lower electrode 11 and the dielectric combination layer may only cover the inner walls of the trench located in the first-type doped region 10, or may cover the inner walls of the trench located in the first-type doped region 10 and part of the inner walls of the trench located in the second-type doped region 18.

Optionally, the top surface of the lower electrode 11 is flush with the top surface of the dielectric combination layer.

The top surface of the upper electrode 13 is flush with the top surface of the dielectric combination layer; or the top surface of the upper electrode 13 protrudes above the top surface of the dielectric combination layer.

Specifically, as shown in FIG. 1, the heights at each of the top surfaces of the lower electrode 11, the stacked dielectric composed of nitride and oxide, and the upper electrode 13 are the same, that is, the lower electrode 11, the stacked dielectric composed of nitride and oxide are both flush with the top surface of the upper electrode 13. In other specific embodiments, those skilled in the art can also make the height of the top surface of the lower electrode 11 the same as the height of the top surface of the stacked structure composed of nitride and oxide according to actual needs, and the upper electrode 13 protrudes above the top surface of the lower electrode 11 in a direction perpendicular to the substrate.

Optionally, the semiconductor structure further includes a capacitor contact structure 17 formed above the upper electrode 13 and connected to the upper electrode.

Optionally, the semiconductor structure further includes the following.

The isolation structure 16 is formed above the lower electrode 11 and covers the top surface of the sidewalls of the lower electrode 11 to isolate the lower electrode 11 from the capacitor contact structure 17.

Specifically, the material of the capacitor contact structure 17 may be an conductive material such as a metal or polysilicon. The specific shape of the capacitor contact structure 17 can be selected according to actual needs by the user, for example, it may be a cylindrical shape extending in a direction perpendicular to the substrate. The capacitor contact structure 17 is disposed on the top surface of the upper electrode 13 and is used to lead out the upper electrode 13 so that the upper electrode 13 is electrically connected to the source S of the transistor (FIG. 3).

To avoid electrical interference between the capacitor contact structure 17 and the lower electrode 11 and to avoid electrical interference between the upper electrode 13 and the lower electrode 11, an isolation structure 16 is disposed on the top surface of the lower electrode 11. For example, the isolation layer 16 may be arranged around the outer circumference of the capacitor contact structure 17. The material of the isolation layer 16 may be, but is not limited to, an oxide material.

Optionally, the stacked structure composed of nitride and oxide includes the following.

An oxide layer 12 is disposed between the lower electrode 11 and the upper electrode 13.

An nitride layer 14 is disposed between the lower electrode 11 and the oxide 12 to prevent the lower electrode 11 from being oxidized.

Optionally, the capacitor further includes an adhesion layer 15 disposed between the oxide layer 12 and the upper electrode 13.

Specifically, in order to prevent the surface of the lower electrode 11 from being oxidized during the process of depositing the oxide layer 12, which affects the conductivity of the lower electrode 11, a nitride layer 14 is arranged between the oxide layer 12 and the lower electrode 11 according to this embodiment. The material of the nitride layer 14 may be silicon nitride. The thickness of the nitride layer 14 is preferably greater than 15 Å.

By disposing the adhesion layer 15 between the oxide layer 12 and the upper electrode 13, the adhering strength between the dielectric combination layer and the upper electrode 13 will be enhanced. The material of the adhesion layer 15 may be a titanium nitride material. The thickness of the adhesion layer 15 is preferably greater than 30 Å.

Optionally, the oxide includes one or a combination of two or more of ZrO₂, Ta₂O₅, Al₂O₃, TiO₂, HfO₂.

Specifically, ZrO₂, Ta₂O₅, Al₂O₃, TiO₂, HfO₂ and other materials have high dielectric constants. Applying a high dielectric constant material in the oxide layer 12 helps to reduce the leakage current inside the capacitor, thereby increasing the capacitance value of the capacitor.

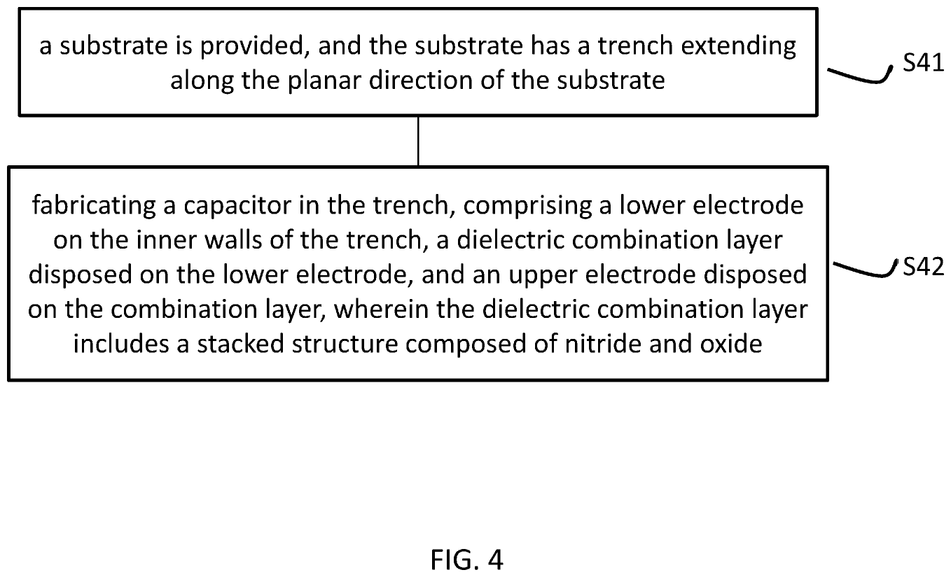

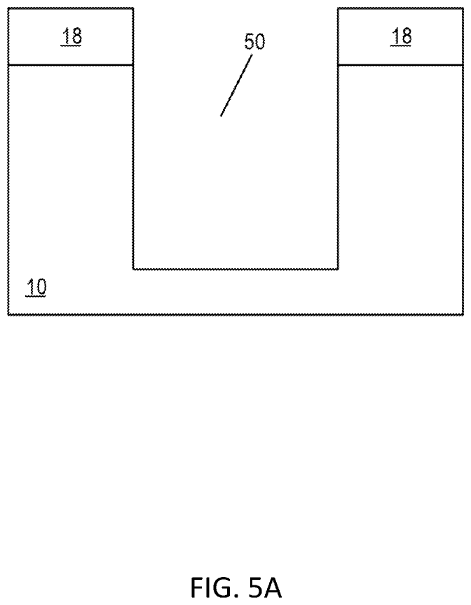

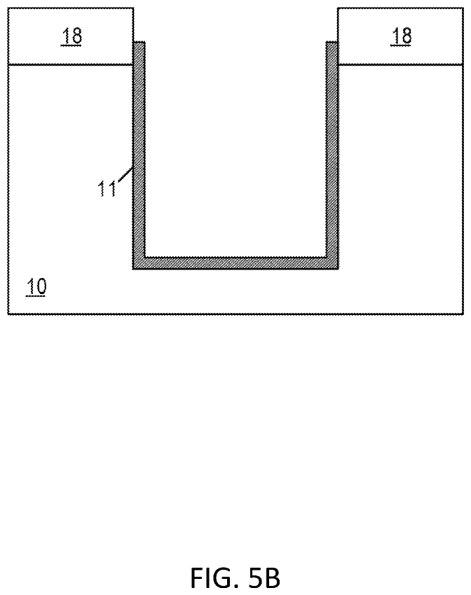

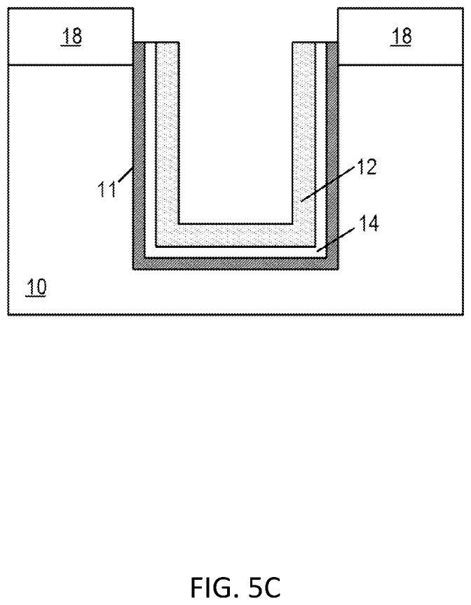

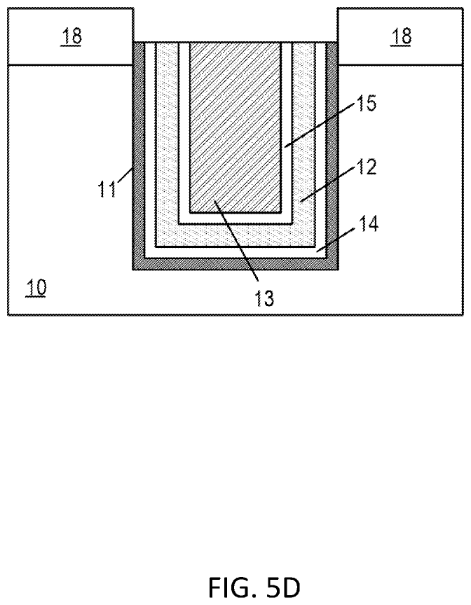

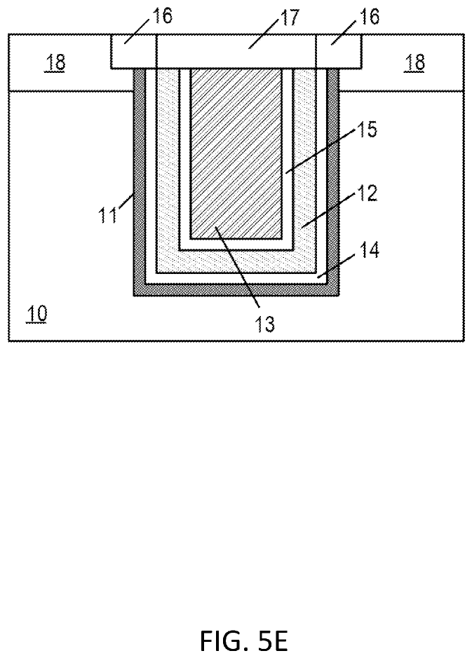

In addition, this disposure also provides a method for forming a semiconductor structure. FIG. 4 shows a schematic flowchart of a method for forming a semiconductor structure in an embodiment of the present disclosure, and FIGS. 5A-5E illustrate a step by step process for forming the semiconductor structure according to an embodiment. FIGS. 1 to 3 illustrate the semiconductor structure formed in this embodiment. Referring to FIGS. 1 to 4 and 5A to 5E, the method for forming the semiconductor structure provided in this embodiment includes the following steps:

In step S41, a substrate is provided, and the substrate has a trench 50 extending along the planar direction of the substrate, as shown in FIG. 5A.

Specifically, the depth and width of the trench 50 can be set according to the size and/or the capacitance of the capacitor required. For example, the depth of the trench 50 is 15 μm-100 μm. The trench 50 may be formed by a dry etching process or a wet etching process.

Step S42, fabricating a capacitor in the trench 50. The capacitor includes a lower electrode 11 disposed on the inner walls of the trench 50, a dielectric combination layer disposed on the lower electrode 11, and an upper electrode 13 disposed on the combination layer, wherein the dielectric combination layer includes a stacked structure composed of nitride and oxide, as shown in FIG. 5E.

Optionally, the substrate includes a first-type doped region 10 and a second-type doped region 18 located above the first-type doped region 10, and the trench 50 passes through the second-type doped region. The second-type doped region 18 extends to the first-type doped region 10. The specific steps of fabricating a capacitor in the trench 50 include the following: forming the lower electrode 11 on the inner walls of the trench 50 in the first-type doped region 10, as shown in FIG. 5B.

Optionally, the steps of fabricating the capacitor in the trench 50 further include: forming a dielectric combination layer in the trench 50 in the first-type doped region 10, and the dielectric combination layer is disposed on the surface of the lower electrode 11.

Specifically, after the trench 50 is formed, the lower electrode 11, the dielectric combination layer, and the upper electrode 13 are sequentially deposited in the trench 50 in the first-type doped region 10. The upper electrode 13 fills the area surrounded by the dielectric combination layer to form a plug shape.

Optionally, after fabricating the capacitor in the trench, the method further includes the following step: a capacitor contact structure 17 electrically connected to the upper electrode 13 is formed above the upper electrode 13.

Optionally, the method for forming the semiconductor structure further includes the following steps: forming an isolation structure 16 above the lower electrode 11, and the isolation structure 16 covers the top surface of the side walls of the lower electrode 11 and is used to isolate the lower electrode 11 and the capacitor contact structure 17.

Optionally, the oxide includes one or a combination of two or more of ZrO2, Ta2O5, Al2O3, TiO2, HfO2.

Hereinafter, for description convenience, assume the material of the lower electrode 11 and the material of the upper electrode 13 are both N-type polysilicon material. After forming the trench 50 as shown in FIG. 5A, a vapor deposition process is applied to deposit polysilicon material on the sidewalls and bottom wall surface of the trench 50 to form an initial lower electrode; then, N-type ions are doped to the initial lower electrode to forms the lower electrode 11, as shown in FIG. 5B. Afterwards, the surface of the lower electrode 11 is subjected to a nitriding treatment, for example, a rapid thermal nitriding process is applied, either nitrogen or ammonia is introduced as a nitrogen source to perform a nitriding treatment on the surface of the lower electrode 11 to form a silicon nitride layer 14. Then, an oxide layer 12 is deposited on the surface of the nitride layer 14 by a vapor deposition process, and the nitride layer 14 and the oxide layer 12 form the stacked structure, as shown in FIG. 5C. Wherein, the oxide layer 12 may be a single-layer structure, or may be a multi-layer structure sequentially stacked along the normal directions of all the inner walls of the trench 50, which can be selected by users according to actual needs. Then, a vapor deposition process is used to deposit an adhesion layer 15 on the surface of the oxide layer 12 and the upper electrode 13 fills the area surrounded by the adhesion layer 15, as shown in FIG. 5D. In the process of forming the upper electrode 13, polysilicon material may be disposed in the area surrounded by the adhesion layer 15 to form an initial upper electrode; then N-type ions are implanted into the initial upper electrode to form the upper electrode 13. FIG. 5D shows the capacitor structure formed in this embodiment. After that, the side of the second-type doped region 18 facing the trench 50 can be etched and deposited to form a ring-shaped isolation structure 16. A conductive material is disposed in the area surrounded by the isolation structure 16 to form the capacitor contact structure 17, as shown in FIG. 5E.

The semiconductor structure and the method for forming the semiconductor structure provided in these embodiments disclose that by forming a trench in the substrate and fabricating the capacitor in the trench, wherein the capacitor includes the upper electrode, the lower electrode, and the dielectric combination layer in between, the electrode surface area of the capacitor is greatly increased, thereby achieving an increase in the capacitance value of the capacitor, so that even as the DRAM size continues to shrink, the capacitance can still maintain a high level; in addition, a dielectric combination layer including a nitride/oxide stack structure is provided between the upper electrode and the lower electrode of the capacitor, such that the dielectric constant of the dielectric combination layer is greatly increased, as the result, the leakage current is effectively improved, the capacitance is increased, and at the end the electrical performance of the semiconductor memory device is improved.

The above disclosed embodiments of the present disclosure are only exemplary. It should be pointed out that several improvements and modifications can be made, for those of ordinary skill in the art, without departing from the principle of the present disclosure, and these improvements and modifications should also be regarded as within the scope of protection of the present disclosure. The present disclosure intends to cover various modifications and equivalent arrangements included in the spirit and scope of the appended claims.

1. A semiconductor structure, comprising:
a substrate comprising a trench extending along a direction of the substrate;
a capacitor fabricated in the trench, wherein the capacitor comprises a lower electrode provided on an inner wall of the trench, a dielectric combination layer provided on the lower electrode, and an upper electrode provided on the dielectric combination layer:
wherein the dielectric combination layer comprises a stacked structure composed of a nitride layer and an oxide layer.

2. The semiconductor structure of claim 1, wherein the substrate further comprises a first-type doped region and a second-type doped region located above the first-type doped region, wherein the trench passes through the second-type doping region and extends to the first-type doped region, and wherein the lower electrode is disposed on the inner wall of the trench in the first-type doped region.

3. The semiconductor structure of claim 2, wherein the dielectric combination layer is disposed in the trench in the first-type doped region.

4. The semiconductor structure of claim 1, further comprising a capacitor contact structure formed above the upper electrode and electrically connected to the upper electrode.

5. The semiconductor structure of claim 4, further comprising an isolation structure formed above the lower electrode, wherein the isolation structure is disposed on a top surface of a side wall of the lower electrode, for isolating the lower electrode from the capacitor contact structure.

6. The semiconductor structure of claim 1, wherein the oxide layer comprises one or more of ZrO2, Ta2O5, Al2O3, TiO2, and HfO2.

7. A method for forming a semiconductor structure, comprising a plurality of steps:
providing a substrate comprising a trench; and
fabricating a capacitor in the trench, wherein the capacitor comprises a lower electrode, a dielectric combination layer disposed on the lower electrode, and an upper electrode.

8. The method for forming the semiconductor structure according to claim 7, wherein the substrate further comprises a first-type doped region and a second-type doped region located above the first-type doped region; and
wherein the fabricating the capacitor in the trench comprises:
forming the lower electrode on the inner wall of the trench in the first-type doped region.

9. The method for forming the semiconductor structure according to claim 8, wherein the dielectric combination layer is disposed in the trench in the first-type doped region.

10. The method for forming the semiconductor structure according to claim 7, wherein after fabricating the capacitor in the trench, the method further comprises forming a capacitor contact structure electrically connected to the upper electrode.

11. The method for forming the semiconductor structure according to claim 10, further comprising forming an isolation structure above the lower electrode.

12. The method for forming the semiconductor structure according to claim 7, wherein the dielectric combination layer comprises one or more of ZrO2, Ta2O5, Al2O3, TiO2, and HfO2.
